(19) United States
(12) Patent Application Publication
(10) Pub. No.: US 2023/0187484 A1
(43) Pub. Date: Jun. 15, 2023

(54) SEMICONDUCTOR DEVICE AND MANUFACTURING METHOD THEREOF

(71) Applicant: AUO Corporation, Hsinchu (TW)

(72) Inventor: Chen-Shuo Huang, Hsinchu (TW)

(73) Assignee: AUO Corporation, Hsinchu (TW)

(21) Appl. No.: 17/992,935

(22) Filed: Nov. 23, 2022

Related U.S. Application Data
(60) Provisional application No. 63/287,695, filed on Dec. 9, 2021.

(30) Foreign Application Priority Data
May 9, 2022 (TW) 111117309

(51) Int. Cl. H01L 29/06; H01L 29/786; H01L 29/417; H01L 29/66; H01L 29/40; H01L 29/423

(52) U.S. Cl. CPC H01L 29/0607; H01L 29/7869; H01L 29/41733; H01L 29/41775; H01L 29/78696; H01L 29/66969; H01L 29/401; H01L 29/42384; H01L 2029/42388

(57) ABSTRACT

A semiconductor device and its manufacturing method are provided. The semiconductor device includes a substrate, a semiconductor structure, a gate dielectric layer, and a gate. The semiconductor structure is disposed above the substrate. The semiconductor structure includes two thick portions and a thin portion located between the two thick portions. A thickness of the two thick portions is larger than a thickness of the thin portion. The gate dielectric layer is disposed on the semiconductor structure. The gate is disposed on the gate dielectric layer. A width of the gate is larger than a width of the thin portion, and the gate is overlapped with a part of the two thick portions and the thin portion in a normal direction of a top surface of the substrate. A resistivity of at least a part of the two thick portions gradually increases with proximity to the substrate.

### CROSS-REFERENCE TO RELATED APPLICATION

This application claims the priority benefit of U.S. provisional application Ser. No. 63/287,695, filed on Dec. 9, 2021 and Taiwan patent application serial no. 111117309, filed on May 9, 2022. The entirety of each of the above-mentioned patent applications is hereby incorporated by reference herein and made a part of this specification.

### BACKGROUND

### Technical Field

The disclosure relates to a semiconductor device and a manufacturing method thereof; more particularly, the disclosure relates to a semiconductor device including a metal oxide semiconductor and a manufacturing method thereof.

### Description of Related Art

Generally, a semiconductor layer of a thin film transistor (TFT) may be divided into a channel region and a doped region. If a carrier concentration of the doped region is high, and if a carrier concentration between the doped region and the channel region is suddenly dropped, a large lateral electric field may be accordingly generated near a drain of the TFT during an operation under a large current, and degradation of the semiconductor device may be induced. However, if the carrier concentration of the doped region is reduced to prevent said degradation of the semiconductor device, an operating current of the semiconductor device may be insufficient. Therefore, how to reduce the lateral electric field near the drain of the semiconductor device while ensuring sufficient performance of an operating current is an issue to be solved at present.

### SUMMARY

The disclosure provides a semiconductor device and a manufacturing method thereof which may reduce a lateral electric field near a drain, so as to improve reliability of the semiconductor device.

In an embodiment of the disclosure, a semiconductor device that includes a substrate, a semiconductor structure, a gate dielectric layer, and a gate is provided. The semiconductor structure is disposed above the substrate and includes two thick portions and a thin portion located between the two thick portions, where a thickness of the two thick portions is larger than a thickness of the thin portion. The gate dielectric layer is disposed on the semiconductor structure. The gate is disposed on the gate dielectric layer. A thickness of the gate is larger than the thickness of the thin portion, and the gate is overlapped with one part of the two thick portions and the thin portion in a normal direction of a top surface of the substrate. A resistivity of at least a part of the two thick portions gradually increases with proximity to the substrate.

In an embodiment of the disclosure, a manufacturing method of a semiconductor device includes following steps. A substrate is provided. A semiconductor structure is formed above the substrate, where the semiconductor structure includes two thick portions and a thin portion located between the two thick portions, and a thickness of the two thick portions is larger than a thickness of the thin portion. A gate dielectric layer is formed on the semiconductor structure. A gate is formed on the gate dielectric layer, where a thickness of the gate is larger than the thickness of the thin portion, and the gate is overlapped with one part of the two thick portions and the thin portion in a normal direction of a top surface of the substrate. A resistivity of the semiconductor structure is adjusted, so that a resistivity of at least a part of the two thick portions gradually increases with proximity to the substrate.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic cross-sectional view of a semiconductor device according to an embodiment of the disclosure.

FIG. 2A to FIG. 2C are schematic cross-sectional flowcharts of a manufacturing process according to the embodiment depicted in FIG. 1.

FIG. 3 is a schematic cross-sectional view of a semiconductor device according to another embodiment of the disclosure.

FIG. 4 is a schematic cross-sectional flowchart of a manufacturing process according to the embodiment depicted in FIG. 3.

FIG. 5 is a schematic cross-sectional view of a semiconductor device according to still another embodiment of the disclosure.

FIG. 6 is a schematic cross-sectional flowchart of a manufacturing process according to the embodiment depicted in FIG. 5.

FIG. 7 is a schematic cross-sectional view of a semiconductor device according to still another embodiment of the disclosure.

FIG. 8A and FIG. 8B are schematic cross-sectional flowcharts of a manufacturing process according to the embodiment depicted in FIG. 7.

### DESCRIPTION OF THE EMBODIMENTS

Reference is now made in detail to exemplary embodiments of the disclosure, and examples of the exemplary embodiments are described in the accompanying drawings. Whenever possible, the same reference numbers are used in the drawings and descriptions to indicate the same or similar parts.

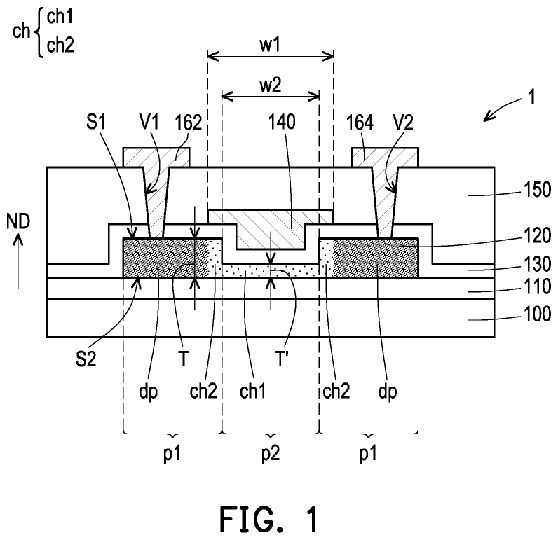

FIG. 1 is a schematic cross-sectional view of a semiconductor device according to an embodiment of the disclosure.

With reference to FIG. 1, a semiconductor device 1 includes a substrate 100, a semiconductor structure 120, a gate dielectric layer 130, and a gate 140. In this embodiment, the semiconductor device 1 further includes a buffer layer 110, an interlayer dielectric layer 150, a source 162, and a drain 164.

A material of the substrate 100 may include glass, quartz, organic polymer, or an opaque/reflective material (e.g., a conductive material, metal, wafer, ceramics, or other applicable materials), or other applicable materials. If the conductive material or the metal is used, the substrate 100 is covered by an insulation layer (not shown) to prevent short circuits. In some embodiments, the substrate 100 is a flexible substrate, and the material of the substrate 100 is, for instance, polyethylene terephthalate (PET), polyethylene naphthalate (PEN), polyester (PES), polymethylmethacrylate (PMMA), polycarbonate (PC), polyimide (PI), metal foil, or other flexible materials. The buffer layer 110 is located on the substrate 100, and a material of the buffer layer 110 may include silicon nitride, silicon oxide, silicon nitride oxide (SiNO), other appropriate materials, or a stacked layer containing said materials, which should however not be construed as a limitation in the disclosure.

The semiconductor structure 120 is disposed above the substrate 100 and the buffer layer 110. The semiconductor structure 120 includes two thick portions p1 and a thin portion p2 located between the two thick portions p1. A material of the semiconductor structure 120 may include quaternary metal compounds, such as indium gallium zinc oxide (IGZO), indium tin zinc oxide (ITZO), aluminum zinc tin oxide (AZTO), indium tungsten zinc oxide (IWZO), and so forth, or may include oxides composed of any three of the following ternary metals: gallium (Ga), zinc (Zn), indium (In), tin (Sn), aluminum (Al), and tungsten (W). The semiconductor structure 120 may be a single-layer structure or a multi-layer structure. The gate dielectric layer 130 is disposed on the semiconductor structure 120 and the buffer layer 110, and the gate 140 is disposed on the gate dielectric layer 130. The interlayer dielectric layer 150 is disposed on the gate dielectric layer 130 and covers the gate 140. A material of the interlayer dielectric layer 150 and the gate dielectric layer 130 includes, for instance, silicon oxide, silicon nitride, SiNO, or other appropriate materials. Through holes V1 and V2 penetrate the interlayer dielectric layer 150 and the gate dielectric layer 130 and are respectively overlapped with the thick portions p1. The source 162 and the drain 164 are located on the interlayer dielectric layer 150 and respectively fill the through holes V1 and V2, so as to be electrically connected to the semiconductor structure 120.

In this embodiment, a thickness T of the two thick portions p1 is larger than a thickness T′ of the thin portion p2. For instance, the thickness T of the two thick portions p1 may be within a range from 7 nm to 120 nm, and the thickness T′ of the thin portion p2 may be within a range from 2 nm to 60 nm. A resistivity of at least a part of the two thick portions p2 gradually increases with proximity to the substrate 100. For instance, a resistivity of one part close to a top surface S1 of the two thick portions p1 is smaller than a resistivity of the other part close to a bottom surface S2 of the two thick portions p1, where the resistivity of the two thick portions p1 may be changed by adjusting a doping concentration or an oxygen vacancy concentration. For instance, in some embodiments, an indium concentration of at least a part of the two thick portions p1 gradually decreases with proximity to the substrate 100; in some embodiments, an oxygen concentration of at least a part of the two thick portions p1 gradually increases with proximity to the substrate 100; in some embodiments, a hydrogen concentration of at least a part of the two thick portions p1 (e.g., the doped region dp of the thick portions p1) gradually decreases with proximity to the substrate 10. Since the thickness T of the two thick portions p1 is larger than the thickness T′ of the thin portion p2, and the resistivity of at least a part of the two thick portions p2 gradually increases with proximity to the substrate 100, hot-carrier effects generated by a lateral electric field near the drain 164 of the semiconductor device 120 may be alleviated.

In this embodiment, a width w1 of the gate 140 is larger than a width w2 of the thin portion p2, and the gate 140 may be overlapped with a part of the two thick portions p1 and the thin portion p2 in a normal direction ND of a top surface of the substrate 100. For instance, the thin portion p2 may be completely overlapped with the gate 140 in a normal direction ND of a top surface of the substrate 100, and a part of the two thick portions p1 may be respectively overlapped with the gate 140 in the normal direction ND of the top surface of the substrate 100. In some embodiment, a ratio of the width w1 of the gate 140 to the width w2 of the thin portion p2 (w1/w2) is 1.05 to 3.

In the semiconductor structure 120, the thin portion p2 may constitute the first channel region ch1, and the two thick portions p2 respectively include the doped region dp and the second channel region ch2. In some embodiments, one part of the two thick portions p1 not overlapped with the gate 140 in the normal direction ND of the top surface of the substrate 100 may be the doped region dp, and the other part of the two thick portions p1 overlapped with the gate 140 in the normal direction ND of the top surface of the substrate 100 may be the second channel region ch2. A hydrogen concentration of the other part of the two thick portions p1 (e.g., the second channel region ch2) close to the thin portion p2 is lower than a hydrogen concentration of the one part of the two thick portions p1 (e.g., the doped region dp) away from the thin portion p2, and a resistivity of the doped region dp gradually increases with proximity to the substrate 100. For instance, a hydrogen concentration of the doped region dp gradually decreases with proximity to the substrate 100, and an oxygen vacancy concentration of the doped region dp gradually decreases with proximity to the substrate 100. Since the resistivity of the doped region dp gradually increases with proximity to the substrate 100, a lower part of the doped region dp at the drain 164 close to the substrate 100 may have a lightly doped drain (LDD) structure, and hot-carrier effects generated by a lateral electric field between the channel region ch (including the first channel region ch1 and the second channel region ch2) and the doped region dp may be further alleviated, so as to improve reliability of the semiconductor device 1. Besides, the source 162 and the drain 164 are in contact with an upper part of the doped region dp with a relatively low resistivity, and therefore an interface resistance between the source 162 and the doped region dp and an interface resistance between the drain 164 and the doped region dp may be reduced, thereby increasing an operating current of the semiconductor device 1.

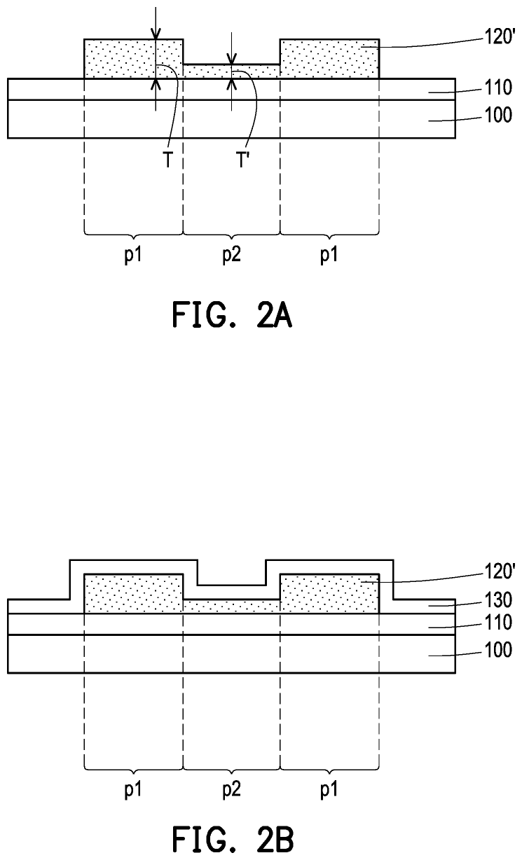

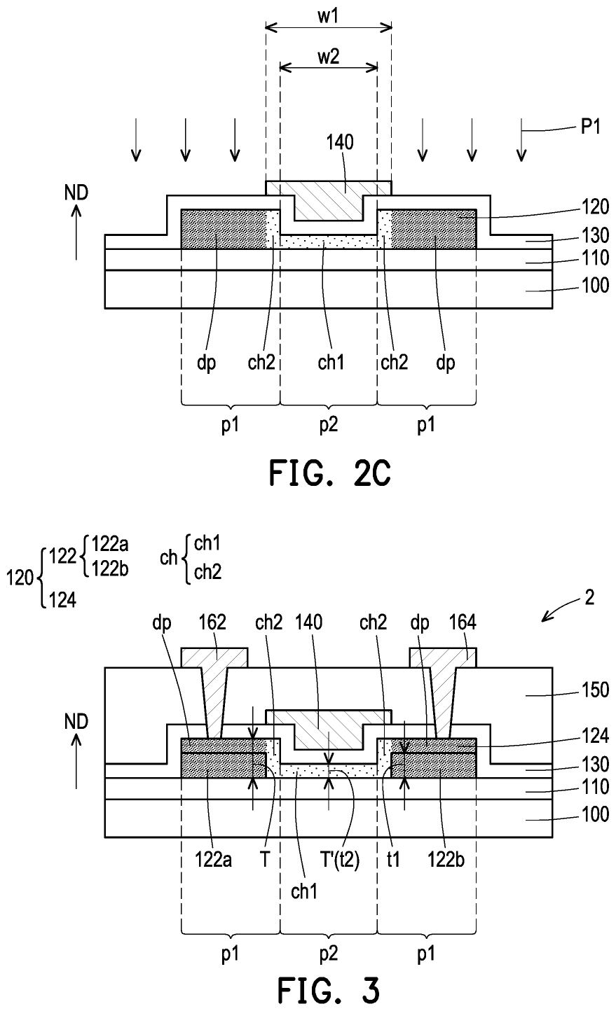

FIG. 2A to FIG. 2C are schematic cross-sectional flowcharts of a manufacturing process according to the embodiment depicted in FIG. 1.

With reference to FIG. 2A, a substrate 100 is provided, and a semiconductor structure 120′ is formed above the substrate 100. For instance, a buffer layer 110 may be formed on the substrate 100 first, and the semiconductor structure 120′ is formed on the buffer layer 110. A method of forming the semiconductor structure 120′ may, for instance, include depositing a metal oxide semiconductor material layer (not shown) on the buffer layer 110 and patterning the metal oxide semiconductor material layer by performing an etching process, so as to form the semiconductor structure 120′. Here, the semiconductor structure 120′ includes two thick portions p1 and a thin portion p2 located between the two thick portions p1, and a thickness T of the two thick portions p1 is larger than a thickness T′ of the thin portion p2.

With reference to FIG. 2B, a gate dielectric layer 130 is formed on the semiconductor structure 120′. For instance, the gate dielectric layer 130 is conformally formed on the semiconductor structure 120′ and the buffer layer 110. Namely, the gate dielectric layer 130 may cover a top surface and sidewalls of the semiconductor structure 120′.

With reference to FIG. 2C, a gate 140 is formed on the gate dielectric layer 130. A method of forming the gate 140 may, for instance, include depositing a gate material layer (not shown) on the gate dielectric layer 130 and performing an etching process to form the gate 140. A width w1 of the gate 140 is larger than a width w2 of the thin portion p2, and the gate 140 may be overlapped with a part of the two thick portions p1 and the thin portion p2 in a normal direction ND of a top surface of the substrate 100.

As shown in FIG. 2C, a resistivity of the semiconductor structure 120 is adjusted, so that a resistivity of at least a part of the two thick portions p2 gradually increases with proximity to the substrate 100. For instance, a doping process P1 is performed on the semiconductor structure 120′ by applying the gate 140 as a mask, so as to form the semiconductor structure 120 including a doped region dp, a first channel region ch1, and a second channel region ch2. The two thick portions p1 of the semiconductor structure 120 not covered by the gate 140 may constitute the doped region dp through the doping process P1, the two thick portions p1 of the semiconductor structure 120 covered by the gate 140 may constitute the second channel region ch2, and a resistivity of the doped region dp gradually increases with proximity to the substrate 100. For instance, in some embodiments, after the doping process P1 is performed, an indium concentration of at least a part of the two thick portions p1 gradually decreases with proximity to the substrate 100, or a hydrogen concentration of at least a part of the two thick portions p1 gradually decreases with proximity to the substrate 100, so as to gradually increase the resistivity of at least a part of the two thick portions p1 with proximity to the substrate 100. In the semiconductor structure 120, the thin portion p2 overlapped with the gate 140 in the normal direction ND of the top surface of the substrate 100 may constitute the first channel region ch1.

In some embodiments, the width w1 of the gate 140 is larger than the width w2 of the thin portion p2, and the gate 140 may be overlapped with a part of the two thick portions p1 and the thin portion p2 in the normal direction ND of the top surface of the substrate 100. Hence, after the doping process P1 is performed, the first channel region ch1 and the second channel region ch2 of different thicknesses may be formed, where the thickness of the second channel region ch2 is larger than the thickness of the first channel region ch1.

Next, with reference to FIG. 1, an interlayer dielectric layer 150 is formed on the gate dielectric layer 130 and covers the gate 140. Through holes V1 and V2 penetrating the interlayer dielectric layer 150 and the gate dielectric layer 130 are formed, and the through holes V1 and V2 are respectively overlapped with the doped region dp of the two thick portions p1 in the normal direction ND of the top surface of the substrate 100. A source 162 and a drain 164 are then formed on the interlayer dielectric layer 150 and fill the through holes V1 and V2, so as to be electrically connected to the doped region dp of the thick portions p1.

After the above process, the fabrication of the semiconductor device 1 is substantially completed.

FIG. 3 is a schematic cross-sectional view of a semiconductor device according to another embodiment of the disclosure. Note that the reference numbers and some contents provided in the embodiment depicted in FIG. 1 are used in the embodiment depicted in FIG. 3, where the same or similar numbers are applied to denote the same or similar elements, and the description of the same technical content is omitted. The description of the omitted content may be found in the previous embodiment and will not be provided hereinafter.

With reference to FIG. 3, the main difference between a semiconductor device 2 shown in FIG. 3 and the semiconductor device 1 shown in FIG. 1 lies in that the semiconductor structure 120 of the semiconductor device 2 includes a first metal oxide semiconductor layer 122 and a second metal oxide semiconductor layer 124, and the first metal oxide semiconductor layer 122 is located between the substrate 100 and the second metal oxide semiconductor layer 124. The stacked first and second metal oxide semiconductor layers 122 and 124 may constitute two thick portions p1 of the semiconductor structure 120. For instance, in this embodiment, the first metal oxide semiconductor layer 122 includes a first island structure 122a and a second island structure 122b separated from each other. The first island structure 122a and the second metal oxide semiconductor layer 124 are stacked to form one of the thick portions p1, and the second island structure 122b and the second metal oxide semiconductor layer 124 are stacked to form the other of the thick portions p1. A part of the second metal oxide semiconductor layer 124 between the two thick portions p1 may constitute the thin portion p2.

In this embodiment, a thickness t1 of the first metal oxide semiconductor layer 122 is larger than a thickness t2 of the second metal oxide semiconductor layer 124. For instance, the thickness t1 of the first metal oxide semiconductor layer 122 may be within a range from 5 nm to 60 nm, and the thickness t2 of the second metal oxide semiconductor layer 124 may be within a range from 2 nm to 60 nm. The thickness T of the two thick portions p1 of the semiconductor structure 120 is substantially the sum of the thickness t1 of the first metal oxide semiconductor layer 122 and the thickness t2 of the second metal oxide semiconductor layer 124, and the thickness T′ of the thin portion p2 of the semiconductor structure 120 is substantially equal to the thickness t2 of the second metal oxide semiconductor layer 124.

In some embodiments, the first metal oxide semiconductor layer 122 and the second metal oxide semiconductor layer 124 may include identical metal elements, which should however not be construed as a limitation in the disclosure. In other embodiments, the first metal oxide semiconductor layer 122 and the second metal oxide semiconductor layer 124 may include different metal elements.

In some embodiments, an oxygen concentration of the first metal oxide semiconductor layer 122 is higher than an oxygen concentration of the second metal oxide semiconductor layer 124, an indium concentration of the first metal oxide semiconductor layer 122 is lower than an indium concentration of the second metal oxide semiconductor layer 124, and a hydrogen concentration of the first metal oxide semiconductor layer 122 is lower than a hydrogen concentration of the second metal oxide semiconductor layer 124. Hence, the resistivity of a part of the two thick portions p1 of the semiconductor structure 120 gradually increases with proximity to the substrate 100, so that a lower part of the doped region dp at the drain 164 close to the substrate 100 may have a LDD structure, and hot-carrier effects generated by the lateral electric field between the channel region ch (including the first channel region ch1 and the second channel region ch2) and the doped region dp may be further alleviated, so as to improve reliability of the semiconductor device 2.

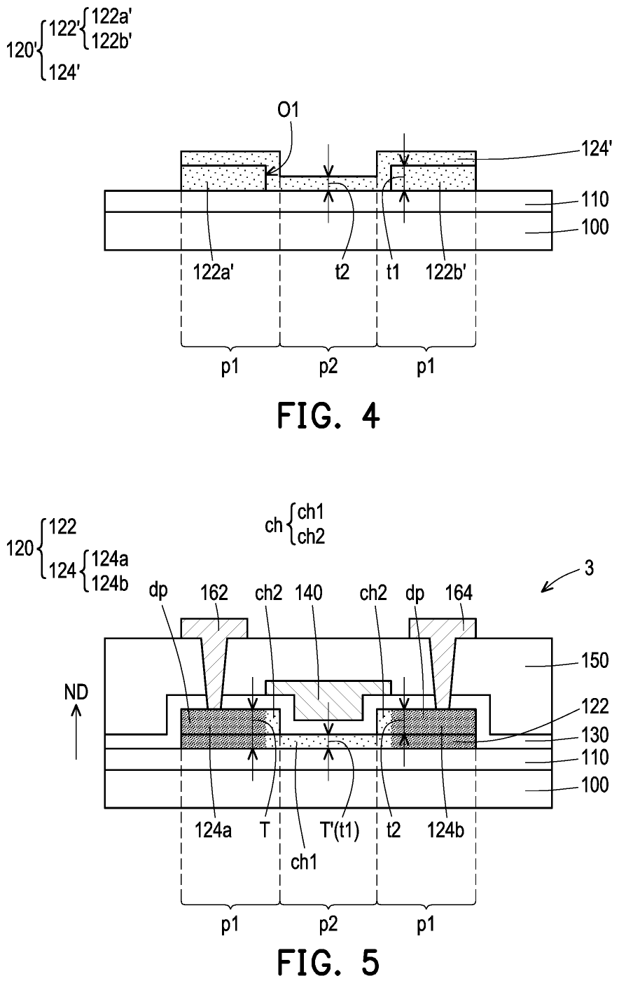

FIG. 4 is a schematic cross-sectional flowchart of a manufacturing process according to the embodiment depicted in FIG. 3.

With reference to FIG. 4, a substrate 100 is provided, and a semiconductor structure 120′ is formed above the substrate 100. For instance, a buffer layer 110 may be formed on the substrate 100 first, and the semiconductor structure 120′ is formed on the buffer layer 110. A method of forming the semiconductor structure 120′ may, for instance, include following steps. A first metal oxide semiconductor layer 122′ is formed on the buffer layer 110 and above the substrate 100, where the first metal oxide semiconductor layer 122′ has a first opening O1, so that the first metal oxide semiconductor layer 122′ includes a first island structure 122a and a second island structure 122b separated from each other. A second metal oxide semiconductor layer 124′ is formed on the first metal oxide semiconductor layer 122′ and fills the first opening O1, where a thickness t1 of the first metal oxide semiconductor layer 122′ is larger than a thickness t2 of the second metal oxide semiconductor layer 124′. As such, one part of the second metal oxide semiconductor layer 124′ filling the first opening O1 may constitute the thin portion p2 of the semiconductor structure 120′, and the first metal oxide semiconductor layer 122′ and the other part of the second metal oxide semiconductor layer 124′ covering the first metal oxide semiconductor layer 122′ may constitute the two thick portions p1 of the semiconductor structure 120′.

With reference to FIG. 3, after the semiconductor structure 120′ is formed, the manufacturing process similar to those depicted in FIG. 2B to FIG. 2C and FIG. 1 may be subsequently performed to complete the fabrication of the semiconductor device 2. The descriptions of the detailed steps may be found in the previous embodiment and will not be provided hereinafter.

FIG. 5 is a schematic cross-sectional view of a semiconductor device according to still another embodiment of the disclosure. Note that the reference numbers and some contents provided in the embodiment depicted in FIG. 1 are used in the embodiment depicted in FIG. 5, where the same or similar numbers are applied to denote the same or similar elements, and the description of the same technical content is omitted. The description of the omitted content may be found in the previous embodiment and will not be provided hereinafter.

With reference to FIG. 5, the main difference between a semiconductor device 3 shown in FIG. 5 and the semiconductor device 1 shown in FIG. 1 lies in that the semiconductor structure 120 of the semiconductor device 3 includes a first metal oxide semiconductor layer 122 and a second metal oxide semiconductor layer 124, and the first metal oxide semiconductor layer 122 is located between the substrate 100 and the second metal oxide semiconductor layer 124. The stacked first and second metal oxide semiconductor layers 122 and 124 may constitute two thick portions p1 of the semiconductor structure 120. For instance, in this embodiment, the second metal oxide semiconductor layer 124 includes a first island structure 124a and a second island structure 124b separated from each other. The first island structure 124a and the first metal oxide semiconductor layer 122 are stacked to form one of the thick portions p1, and the second island structure 124b and the first metal oxide semiconductor layer 122 are stacked to form the other of the thick portions p1. A part of the first metal oxide semiconductor layer 122 between the two thick portions p1 may constitute the thin portion p2.

In this embodiment, a thickness t1 of the first metal oxide semiconductor layer 122 is smaller than a thickness t2 of the second metal oxide semiconductor layer 124. For instance, the thickness t1 of the first metal oxide semiconductor layer 122 may be within a range from 2 nm to 60 nm, and the thickness t2 of the second metal oxide semiconductor layer 124 may be within a range from 5 nm to 60 nm. The thickness T of the two thick portions p1 of the semiconductor structure 120 is substantially the sum of the thickness t1 of the first metal oxide semiconductor layer 122 and the thickness t2 of the second metal oxide semiconductor layer 124, and the thickness T′ of the thin portion p2 of the semiconductor structure 120 is substantially equal to the thickness t1 of the first metal oxide semiconductor layer 122.

In some embodiments, the first metal oxide semiconductor layer 122 and the second metal oxide semiconductor layer 124 may include identical metal elements, which should however not be construed as a limitation in the disclosure. In other embodiments, the first metal oxide semiconductor layer 122 and the second metal oxide semiconductor layer 124 may include different metal elements.

In some embodiments, an oxygen concentration of the first metal oxide semiconductor layer 122 is higher than an oxygen concentration of the second metal oxide semiconductor layer 124, an indium concentration of the first metal oxide semiconductor layer 122 is lower than an indium concentration of the second metal oxide semiconductor layer 124, and a hydrogen concentration of the first metal oxide semiconductor layer 122 is lower than a hydrogen concentration of the second metal oxide semiconductor layer 124. Hence, the resistivity of a part of the two thick portions p1 of the semiconductor structure 120 gradually increases with proximity to the substrate 100, so that a lower part of the doped region dp at the drain 164 close to the substrate 100 may have a LDD structure, and hot-carrier effects generated by the lateral electric field between the channel region ch (including the first channel region ch1 and the second channel region ch2) and the doped region dp may be further alleviated, so as to improve reliability of the semiconductor device 3.

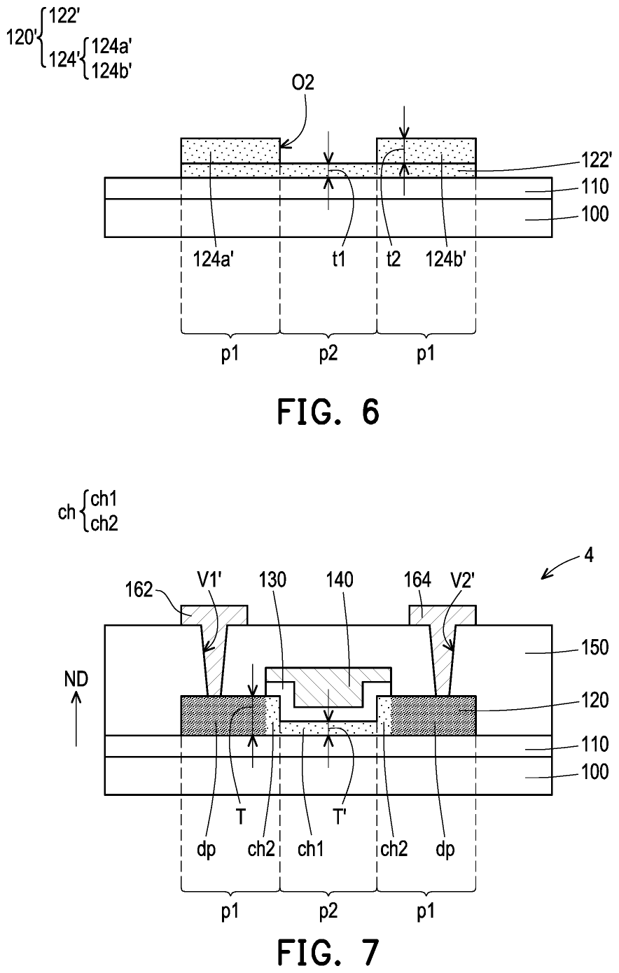

FIG. 6 is a schematic cross-sectional flowchart of a manufacturing process according to the embodiment depicted in FIG. 5.

With reference to FIG. 6, a substrate 100 is provided, and a semiconductor structure 120′ is formed on the substrate 100. For instance, a buffer layer 110 may be formed on the substrate 100 first, and the semiconductor structure 120′ is formed on the buffer layer 110. A method of forming the semiconductor structure 120′ may, for instance, include following steps. A first metal oxide semiconductor layer 122′ is formed on the buffer layer 110 and above the substrate 100, and a second metal oxide semiconductor layer 124′ is formed on the first metal oxide semiconductor layer 122′. The second metal semiconductor layer 124′ has a second opening O2 to expose one part of the first metal oxide semiconductor layer 122′, and second metal semiconductor layer 124′ includes a first island structure 124a′ and a second island structure 124b′ separated from each other. A thickness t1 of the first metal oxide semiconductor layer 122′ is smaller than a thickness t2 of the second metal oxide semiconductor layer 124′. As such, the one part of the first metal oxide semiconductor layer 122′ exposed by the second opening O2 may constitute the thin portion p2 of the semiconductor structure 120′, and the second metal oxide semiconductor layer 124′ and the other part of the first metal oxide semiconductor layer 122′ covered by the second metal oxide semiconductor layer 124′ may constitute the two thick portions p1 of the semiconductor structure 120′.

With reference to FIG. 5, after the semiconductor structure 120 is formed, the manufacturing process similar to those depicted in FIG. 2B to FIG. 2C and FIG. 1 may be subsequently performed to complete the fabrication of the semiconductor device 3. The descriptions of the detailed steps may be found in the previous embodiment and will not be provided hereinafter.

FIG. 7 is a schematic cross-sectional view of a semiconductor device according to still another embodiment of the disclosure. Note that the reference numbers and some contents provided in the embodiment depicted in FIG. 1 are used in the embodiment depicted in FIG. 7, where the same or similar numbers are applied to denote the same or similar elements, and the description of the same technical content is omitted. The description of the omitted content may be found in the previous embodiment and will not be provided hereinafter.

With reference to FIG. 7, the main difference between a semiconductor device 4 shown in FIG. 7 and the semiconductor device 1 shown in FIG. 1 lies in that the gate dielectric layer 130 of the semiconductor device 4 is located between the gate 140 and the semiconductor structure 120, while a part of the two thick portions p1 not overlapped with the gate 140 in the normal direction ND of the top surface of the substrate 100 is not covered by the gate dielectric layer 130. Through holes V1′ and V2′ are separated from the gate dielectric layer 130 and are respectively overlapped with the two thick portions p1 in the normal direction ND of the top surface of the substrate 100. The source 162 and the drain 164 are located on the interlayer dielectric layer 150 and respectively fill the through holes V1′ and V2′ to be electrically connected to the semiconductor structure 120.

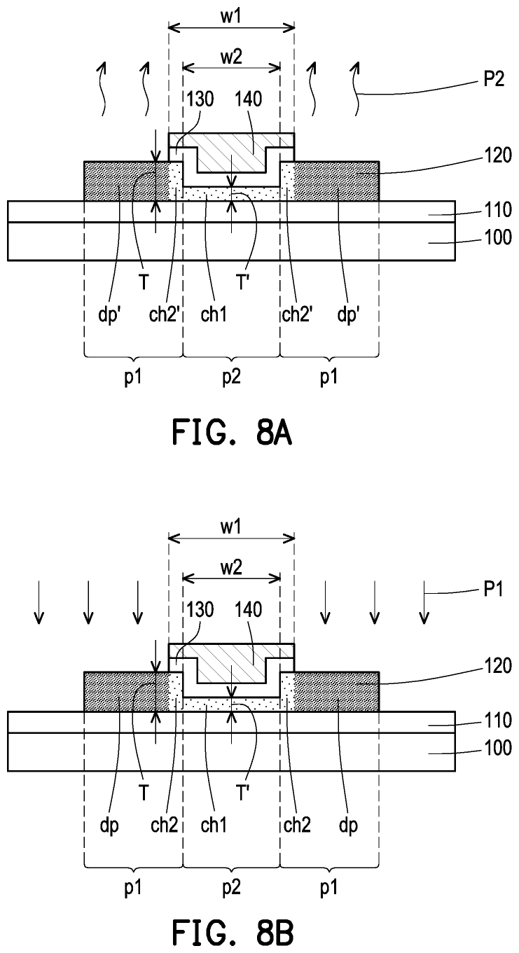

FIG. 8A and FIG. 8B are schematic cross-sectional flowcharts of a manufacturing process according to the embodiment depicted in FIG. 7. Here, FIG. 8A may be considered as a schematic cross-sectional view of the manufacturing method of the semiconductor device following the steps depicted in FIG. 2B. The descriptions of the detailed steps depicted in FIG. 2A and FIG. 2B may be found in the previous embodiment and will not be provided hereinafter.

With reference to FIG. 8A, the gate 140 is formed on the gate dielectric layer 130. A width w1 of the gate 140 is larger than a width w2 of the thin portion p2, and the gate 140 may be overlapped with a part of the two thick portions p1 and the thin portion p2 in a normal direction ND of a top surface of the substrate 100.

As shown in FIG. 8A, a resistivity of the semiconductor structure 120 is adjusted, so that a resistivity of at least a part of the two thick portions p2 gradually increases with proximity to the substrate 100. In this embodiment, a part of the gate dielectric layer 130 is removed to expose a part of the two thick portions p1 not overlapped with the gate 140 in the normal direction ND of the top surface of the substrate 100. A method of removing a part of the gate dielectric layer 130 may, for instance, include performing a dry etching process or a wet etching process on the gate dielectric layer 130 by applying the gate 140 as a mask, which should however not be construed as a limitation in the disclosure. An annealing process P2 is then performed. An annealing temperature at which the annealing process P2 is performed may be within a range from 200° C. to 400° C. Since the gate dielectric layer 130 exposes a part of the two thick portions p1 not overlapped with the gate 140 in the normal direction ND of the top surface of the substrate 100, oxygen in the two thick portions p1 may be dissipated to the outside from a surface of the exposed part of the two thick portions p1, whereby a first part dp′ of the thick portions p1 with higher oxygen vacancy and lower resistivity and a second part ch2′ of the thick portions p1 with lower oxygen vacancy and higher resistivity are formed. Here, the second part ch2′ is covered by the gate dielectric layer 130, and the first part dp′ is exposed by the gate dielectric layer 130. In this embodiment, the oxygen close to the surface of the thick portions p1 is more likely to be dissipated to the outside; therefore, by performing the annealing process P2, the oxygen concentration of the first part dp′ of the two thick portions p1 gradually increases with proximity to the substrate 100, and the number of oxygen vacancies in the first part dp′ of the two thick portions p1 gradually decreases with proximity to the substrate 100. Accordingly, the resistivity of the first part dp′ of the two thick portions p1 gradually increases with proximity to the substrate 100.

With reference to FIG. 8B, after the annealing process P2 is performed, a doping process P1 is performed on the first part dp′ of the thick portions p1 by applying the gate 140 as a mask, so as to form the doped region dp and the second channel region ch2 in the thick portions p1. Here, the doped region dp corresponds to the first part dp′, and the second channel region ch2 corresponds to the second part ch2′, which should however not be construed as a limitation in the disclosure. In other embodiments, after the annealing process P2 is performed, it is likely not to perform the hydrogen plasma process P1.

With reference to FIG. 7, the interlayer dielectric layer 150 is formed above the buffer layer 110 and covers the gate 140 and the semiconductor structure 120. After that, through holes V1 ‘ and V2 ’ penetrating the interlayer dielectric layer 150 are formed, and the through holes V1′ and V2′ are respectively overlapped with the two thick portions p1. A source 162 and a drain 164 are then formed above the interlayer dielectric layer 150 and fill the through holes V1′ and V2′, so as to be electrically connected to the doped region dp of the semiconductor structure 120.

In this embodiment, the semiconductor structure 120 is, for instance, a single-layer structure, which should however not be construed as a limitation in the disclosure. In other embodiments, the semiconductor structure 120 may refer to the semiconductor structure 120′ shown in FIG. 4 or FIG. 6.

After the above process, the fabrication of the semiconductor device 4 is substantially completed.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A semiconductor device, comprising:
a substrate;
a semiconductor structure, disposed above the substrate and comprising two thick portions and a thin portion located between the two thick portions, wherein a thickness of the two thick portions is larger than a thickness of the thin portion;
a gate dielectric layer, disposed on the semiconductor structure; and
a gate, disposed on the gate dielectric layer, wherein a thickness of the gate is larger than the thickness of the thin portion, and the gate is overlapped with one part of the two thick portions and the thin portion in a normal direction of a top surface of the substrate,
wherein a resistivity of at least a part of the two thick portions gradually increases with proximity to the substrate.

2. The semiconductor device according to claim 1, wherein the semiconductor structure comprises a first metal oxide semiconductor layer and a second metal oxide semiconductor layer, the first metal oxide semiconductor layer is located between the substrate and the second metal oxide semiconductor layer, and the first metal oxide semiconductor layer and the second metal oxide semiconductor layer are stacked to form the two thick portions.

3. The semiconductor device according to claim 2, wherein the second metal oxide semiconductor layer comprises a first island structure and a second island structure separated from each other, the first island structure and the first metal oxide semiconductor layer are stacked to form one of the thick portions, and the second island structure and the first metal oxide semiconductor layer are stacked to form the other of the thick portions.

4. The semiconductor device according to claim 3, wherein the thin portion comprises a part of the first metal oxide semiconductor layer between the two thick portions, and a thickness of the first metal oxide semiconductor layer is smaller than a thickness of the second metal oxide semiconductor layer.

5. The semiconductor device according to claim 2, wherein the first metal oxide semiconductor layer comprises a first island structure and a second island structure separated from each other, the first island structure and the second metal oxide semiconductor layer are stacked to form one of the thick portions, and the second island structure and the second metal oxide semiconductor layer are stacked to form the other of the thick portions.

6. The semiconductor device according to claim 5, wherein the thin portion comprises a part of the second metal oxide semiconductor layer between the two thick portions, and a thickness of the first metal oxide semiconductor layer is larger than a thickness of the second metal oxide semiconductor layer.

7. The semiconductor device according to claim 2, wherein the first metal oxide semiconductor layer and the second metal oxide semiconductor layer comprise identical metal elements.

8. The semiconductor device according to claim 2, wherein the first metal oxide semiconductor layer and the second metal oxide semiconductor layer comprise different metal elements.

9. The semiconductor device according to claim 1, wherein the thickness of the two thick portions is within a range from 7 nm to 120 nm, and the thickness of the thin portion is within a range from 2 nm to 60 nm.

10. The semiconductor device according to claim 2, wherein an oxygen concentration of the first metal oxide semiconductor layer is higher than an oxygen concentration of the second metal oxide semiconductor layer, and an indium concentration of the first metal oxide semiconductor layer is lower than an indium concentration of the second metal oxide semiconductor layer.

11. The semiconductor device according to claim 1, wherein a hydrogen concentration of one part of the two thick portions close to the thin portion is lower than a hydrogen concentration of the other part of the two thick portions away from the thin portion.

12. A manufacturing method of a semiconductor device, comprising:
providing a substrate;
forming a semiconductor structure above the substrate, wherein the semiconductor structure comprises two thick portions and a thin portion located between the two thick portions, and a thickness of the two thick portions is larger than a thickness of the thin portion;
forming a gate dielectric layer on the semiconductor structure;
forming a gate on the gate dielectric layer, wherein a thickness of the gate is larger than the thickness of the thin portion, and the gate is overlapped with one part of the two thick portions and the thin portion in a normal direction of a top surface of the substrate; and
adjusting a resistivity of the semiconductor structure, so that a resistivity of at least a part of the two thick portions gradually increases with proximity to the substrate.

13. The manufacturing method according to claim 12, wherein the step of adjusting the resistivity of the semiconductor structure comprises:
performing a doping process on the other part of the two thick portions not overlapped with the gate in the normal direction of the top surface of the substrate.

14. The manufacturing method according to claim 12, wherein the step of adjusting the resistivity of the semiconductor structure comprises:
removing a part of the gate dielectric layer to expose the other part of the two thick portions not overlapped with the gate in the normal direction of the top surface of the substrate; and
performing an annealing process, so that oxygen in the two thick portions is dissipated to the outside from a surface of the two thick portions, and that an oxygen concentration of the two thick portions gradually increases with proximity to the substrate.

15. The manufacturing method according to claim 14, wherein an annealing temperature at which the annealing process is performed is within a range from 200° C. to 400° C.

16. The manufacturing method according to claim 12, wherein the step of forming the semiconductor structure above the substrate comprises:
forming a first metal oxide semiconductor layer above the substrate, wherein the first metal oxide semiconductor layer has a first opening; and
forming a second metal oxide semiconductor layer on the first metal oxide semiconductor layer and filling the first opening with the second metal oxide semiconductor layer, wherein a thickness of the first metal oxide semiconductor layer is larger than a thickness of the second metal oxide semiconductor layer;
wherein one part of the second metal oxide semiconductor layer filling the first opening constitutes the thin portion, and the first metal oxide semiconductor and the other part of the second metal oxide semiconductor covering the first metal oxide semiconductor constitute the two thick portions.

17. The manufacturing method according to claim 12, wherein the step of forming the semiconductor structure above the substrate comprises:
forming a first metal oxide semiconductor layer above the substrate; and
forming a second metal oxide semiconductor layer on the first metal oxide semiconductor layer, wherein the second metal oxide semiconductor layer has a second opening to expose one part of the first metal oxide semiconductor layer,
wherein a thickness of the first metal oxide semiconductor layer is smaller than a thickness of the second metal oxide semiconductor layer,
wherein the one part of the first metal oxide semiconductor layer exposed by the second opening constitutes the thin portion, and the second metal oxide semiconductor layer and the other part of the first metal oxide semiconductor layer covered by the second metal oxide semiconductor layer constitute the two thick portions.
